(19) United States
(12) Patent Application Publication
(10) Pub. No.: US 2010/0047987 A1
(43) Pub. Date: Feb. 25, 2010

(54) METHOD OF FABRICATING A BIPOLAR TRANSISTOR

(75) Inventors: Johannes Josephus Theodorus Marin Donkers, Valkenswaard (NL); Erwin Hijzen, Blanden (BE); Wibo Daniel Van Noort, Wappingers Falls, NY (US)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 11/913,048

(22) PCT Filed: Apr. 24, 2006
(86) PCT No.: PCT/IB2006/051261

§ 371 Date: Nov. 13, 2009

(30) Foreign Application Priority Data
Apr. 28, 2005 (EP) 05103521.0

(51) Int. Cl. H01L 21/331

(52) U.S. Cl. 438/318; 257/E21.371

(57) ABSTRACT

The invention provides a method for fabricating a bipolar transistor applying a standard shallow trench isolation fabrication method to simultaneously form a vertical bipolar transistor (29) or a lateral bipolar transistor (49) in a first trench (5, 50) and a shallow trench isolation region (27, 270) in a second trench (7, 70). Further, the fabrication method may simultaneously form a vertical bipolar transistor (27) in the first trench (5, 50), a lateral bipolar transistor (49) in a third trench and a shallow trench isolation region (27, 270) in the second trench (7, 70).

In WO 03/100845 a fabrication method of a bipolar transistor is disclosed, in which a substrate is provided with two shallow trench isolation regions with an n-type epitaxial collector region in between and an insulating layer covering the substrate. A layer structure including a conductive layer is formed on the insulating layer, after which a window or trench is etched through the conductive layer. In this trench a SiGe heterojunction bipolar transistor is fabricated. The disadvantage of this method is that an extra layer and a separate masking step are required to form the trench in which the bipolar transistor is fabricated.

It is an object of the invention to provide a method for fabricating a bipolar transistor in a trench with a minimum number of additional fabrication steps. According to the invention, this object is achieved by providing a method as claimed in claim 1.

The invention provides a method for fabricating a bipolar transistor applying a standard shallow trench isolation fabrication method to simultaneously form a bipolar transistor in a first trench and a shallow trench isolation region in a second trench. For this purpose a first insulation layer is provided on a further substrate region, which overlies a substrate region. The first trench and the second trench, each having a bottom, are formed simultaneously in the first insulation layer and in the further substrate region. Subsequently the second trench is filled with a second insulation layer. A first transistor region is formed in a portion of the further substrate region, which is located at the bottom of the first trench, and a second transistor region is formed on a portion of the first transistor region. Thereafter a third transistor region is formed on a portion of the second transistor region. A bipolar transistor is then formed in the first trench and simultaneously a shallow trench isolation region is formed in the second trench by a planarization of the exposed surfaces after which the first insulation layer is exposed. The fabrication method advantageously uses the trenches fabricated with the standard shallow trench isolation fabrication method, to fabricate a bipolar transistor in the first trench and simultaneously fabricate a shallow trench isolation region in the second trench, thereby saving the fabrication steps of forming a separate trench for the bipolar transistor only.

In a first embodiment a vertical bipolar transistor is formed in the first trench, wherein the first transistor region comprises a collector region, the second transistor region comprises a first base region and the third transistor region comprises an emitter region.

In a second embodiment a lateral bipolar transistor is formed in the first trench, wherein the first transistor region comprises a first base region, the second transistor region comprises a second base region, a portion of the further substrate region adjacent to the first trench comprises a further emitter region and another portion of the further substrate region, which is adjacent to the first trench and opposite to the further emitter region, comprises a further collector region. The further collector region and the further emitter region are located on opposite sides of the first trench.

In a third embodiment a vertical bipolar transistor is formed in the first trench and simultaneously a lateral bipolar transistor is formed in a third trench.

These and other aspects of the invention will be further elucidated and described with reference to the drawings, in which:

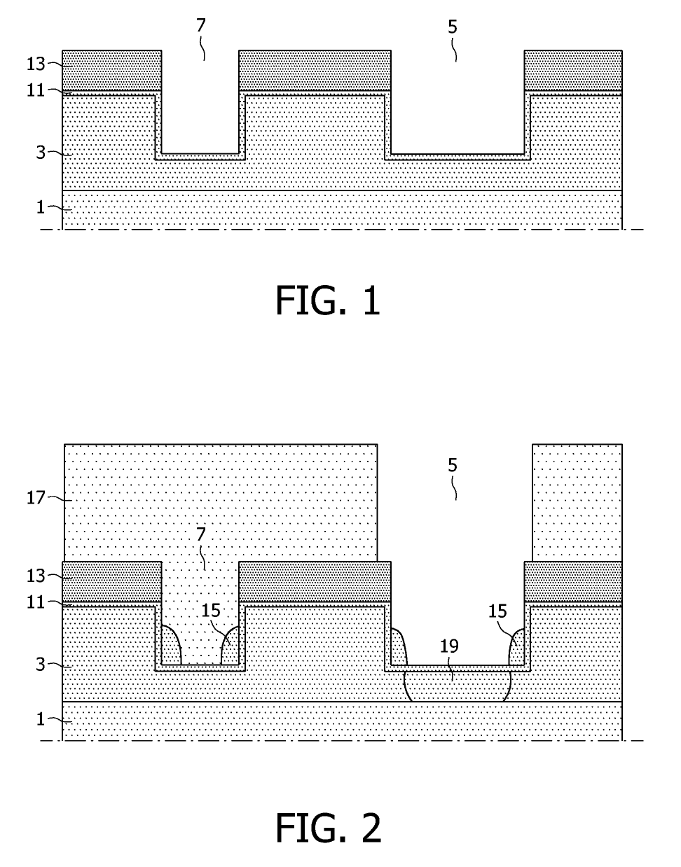

FIGS. 1-7 illustrate cross-sectional views of the various stages of the fabrication of a vertical bipolar transistor according to the invention, and

FIGS. 8-13 illustrate cross-sectional views of the various stages of the fabrication of a lateral bipolar transistor according to the invention.

The Figures are not drawn to scale. In general, identical components are denoted by the same reference numerals in the figures.

The fabrication method starts with the result of the first fabrication steps of a standard shallow trench isolation (STI) fabrication method as is illustrated in FIG. 1. A silicon on insulator (SOI) substrate is provided, which comprises a substrate insulation region 1 and a substrate region 3 overlying the substrate insulation region 1. Alternatively a standard semiconductor substrate without the substrate insulation region 1 may be applied. The substrate insulation region 1 may comprise silicon dioxide, and the substrate region 3 may comprise a semiconductor material, such as for example n-type silicon. A first trench 5 and a second trench 7 are provided in the substrate region 3, whereby the bottom of the first trench 5 and the bottom of the second trench 7 both expose the substrate region 3. Further, the bottom and the sidewalls of the first trench 5 and the second trench 7 are covered with a first insulation liner layer 11, and the substrate region 3 adjacent to the first trench 5 and the second trench 7 is covered with the first insulation liner layer 11 on which a first insulation layer 13 is formed. The first insulation liner layer 11 may comprise silicon dioxide, and the first insulation layer 13 may comprise silicon nitride. Standard CMOS and other semiconductor devices may be fabricated in a later stage in the substrate region 3 adjacent to the first trench 5 and the second trench 7.

As is shown in FIG. 2, first spacers 15 are formed in the first trench 5 and in the second trench 7 using standard spacer forming techniques. The first spacers 15 may comprise amorphous silicon and preferably have a D-sized shape. In a later stage it will become clear that the first spacers 15 are provided to limit the collector to base capacitance. The first spacers 15 are not part of the standard STI fabrication method, however, they may be omitted, as will be explained in the next stage of the fabrication method. A second insulation layer 17 is deposited, in which for example high-density plasma (HDP) silicon dioxide may be applied. The second insulation layer 17 fills the first trench 5 and the second trench 7 and covers the first insulation layer 13. From this point onwards the fabrication method deviates from the standard STI fabrication method. A photolithographic step is applied to mask the future STI regions, in this case the second trench 7, with a resist layer and to expose the trenches in which a vertical bipolar transistor will be fabricated, in this case the first trench 5. FIG. 2 shows that the second insulation layer 17 is removed from the first trench 5 using a dry etching method that hardly etches silicon. Alternatively only a portion of the first trench 5 may be opened whereby the fabrication of the first spacers 15 may be omitted. The resist layer is removed and a collector region 19 is formed by implantation of an n-type dopant, such as arsenic or phosphorous. The bottom of the first trench 5 forms the top of the collector region 19, which reaches through to the substrate insulation region 1, whereby the collector region 19 replaces the portion of the substrate region 3 that is located at the bottom of the first trench 5. The first spacers 15 may also be fabricated after the removal of the resist layer and before the forming of the collector region 19.

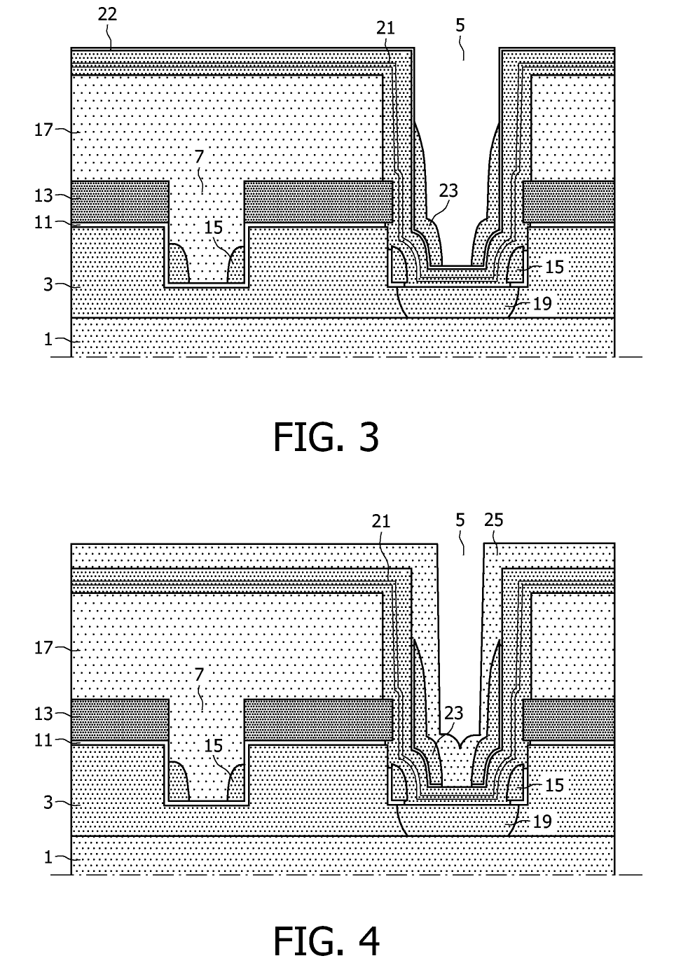

A wet etch removes the portion of the first insulation liner layer 11 which is exposed in the first trench 5. Thereafter a base region 21 is formed with epitaxial growth covering all exposed surfaces, as is illustrated in FIG. 3. The base region 21 preferably comprises a SiGe:C layer, but any other p-type semiconductor material may also be applied. A portion of the base region 21 covers a portion of the collector region 19, thereby forming a base-collector junction in the first trench 5. Next a second insulation liner layer 22 is deposited on the base region 21, and second spacers 23 are formed by depositing and anisotropic etching of silicon nitride. The second insulation liner layer 22 may comprise for example silicon dioxide.

Thereafter, a wet etch removes the exposed portions of the second insulation liner layer 22, in particular the exposed portion which covers the portion of the base region 21 that covers the portion of the collector region 19. An emitter region 25 is formed by deposition or growth of an n-type polysilicon or mono-silicon layer, as is shown in FIG. 4. A portion of the emitter region 25 covers a portion of the base region 21 which covers a portion of the collector region 19, thereby forming an emitter-base junction in the first trench 5.

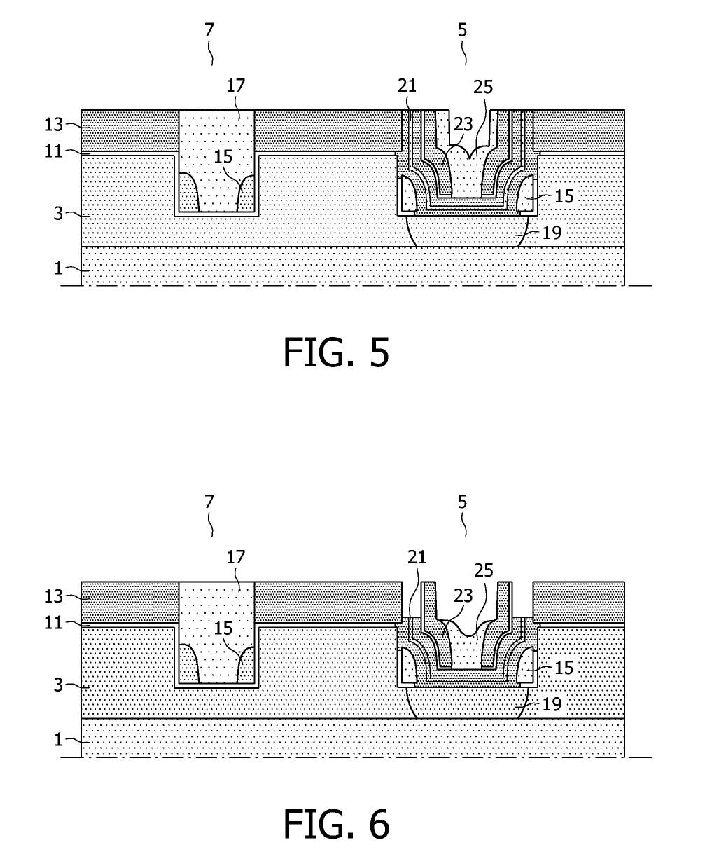

At this point the standard STI fabrication method is continued with planarizing the surface using chemical mechanical polishing (CMP). In this case however, the CMP method should be able to planarize not only the second insulation layer 17, but also the emitter region 25 and the base region 21, which regions may comprise mono-silicon, poly-silicon or SiGe. As is illustrated in FIG. 5, the first insulation layer 13 and a top portion of the second spacers 23 are exposed after the planarization.

Thereafter a portion of the base region 21 and a portion of the emitter region 25 are removed by an isotropic silicon etch or a wet oxidation step, as is illustrated in FIG. 6. This fabrication step is introduced in the standard STI fabrication method to enable an improved planar surface of the vertical bipolar transistor.

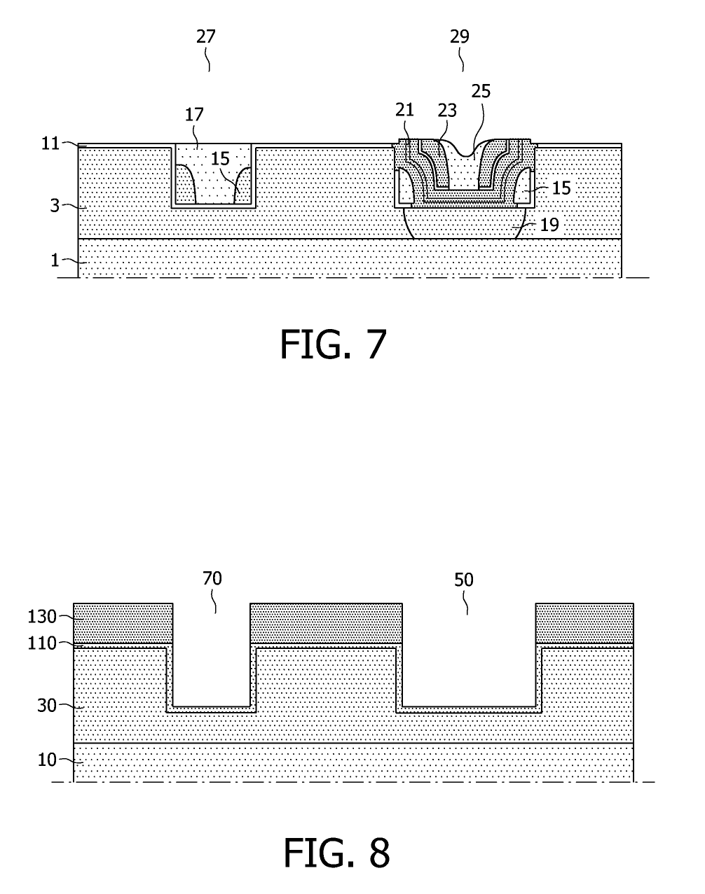

The standard STI fabrication method continues with a wet etch thereby removing the first insulation layer 13, a portion of the second insulation layer 17 and a portion of the second spacers 23, which results in a planar surface as is illustrated in FIG. 7. At this point a vertical bipolar transistor 29 is formed in the first trench 5 comprising the collector region 19, the base region 21 and the emitter region 25. Further, an STI region 27 is formed simultaneously in the second trench 7, which is filled with the second insulation layer 17. In summary, the fabrication method has formed a vertical bipolar transistor in a trench, which is normally used as a trench for an STI region.

From this point onwards the standard semiconductor fabrication continues with the forming of other devices, such as CMOS transistors. The vertical bipolar transistor may be covered with an insulation layer to reduce the influence of the further fabrication steps on the vertical bipolar transistor. This insulation layer may be patterned using an existing mask, such as a silicide protection mask. A base contact region, which connects electrically to the base region 21, may be formed by providing a metal layer on exposed portions of the substrate region 3 which are adjacent to the first trench 5. The source/drain implantations for the CMOS transistors may be applied to the base contact region, thereby advantageously lowering the base resistance. A collector contact region, which connects electrically to the collector region 19, may be formed by removing a portion of the substrate insulation region 1 and providing a metal layer on the exposed area of the collector region 19. An emitter contact region, which connects electrically to the emitter region 25, may be formed by providing a metal layer on the emitter region 25.

The various stages of the fabrication of a lateral bipolar transistor according to the invention are illustrated in the cross-sectional views of FIGS. 8-13.

The fabrication method of the lateral bipolar transistor starts with the situation as is illustrated in FIG. 8, which is also the starting point for the fabrication of the vertical bipolar transistor. A silicon on insulator (SOI) substrate is provided, which comprises a substrate insulation region 10 and a substrate region 30 overlying the substrate insulation region 10. The substrate insulation region 10 may comprise silicon dioxide, and the substrate region 30 may comprise a semiconductor material, such as for example n-type silicon. A first trench 50 and a second trench 70 are provided in the substrate region 30, whereby the bottom of the first trench 50 and the second trench 70 expose the substrate region 30. Further, the bottom and the sidewalls of the first trench 50 and the second trench 70 are covered with a first insulation liner layer 110, and the substrate region 3 adjacent to the first trench 50 and the second trench 70 is covered with the first insulation liner layer 110 on which a first insulation layer 130 is formed. The first insulation liner layer 110 may comprise silicon dioxide, and the first insulation layer 130 may comprise silicon nitride. Standard CMOS and other semiconductor devices may be fabricated in a later stage in the substrate region 30 adjacent to the first trench 50 and the second trench 70.

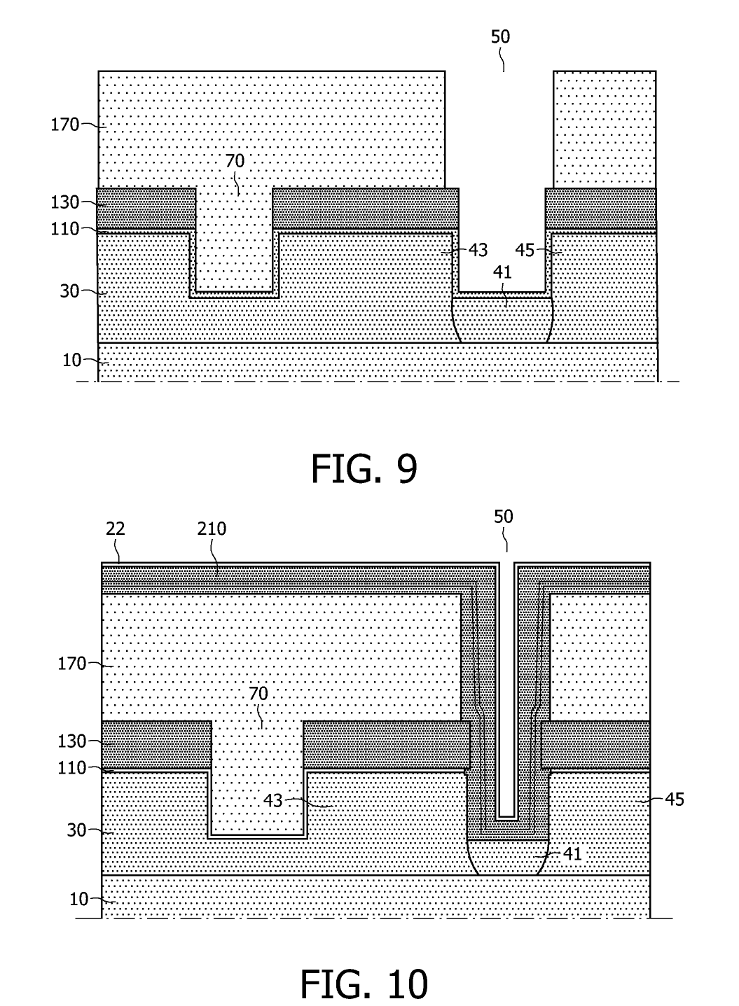

As is shown in FIG. 9, a second insulation layer 170 is deposited, in which for example high-density plasma (HIDP) silicon dioxide may be applied. The second insulation layer 170 fills the first trench 50 and the second trench 70 and covers the first insulation layer 130. From this point onwards the fabrication method deviates from the standard STI fabrication method. A photolithographic step is applied to mask the future STI regions, in this case the second trench 70, with a resist layer and to expose the trenches in which a lateral bipolar transistor will be fabricated, in this case the first trench 50. FIG. 9 shows that the second insulation layer 170 is removed from the first trench 50 using a dry etching method that hardly etches silicon. Further, a portion of the substrate region 30 adjacent to the first trench 50 comprises a further collector region 43 and another portion of the substrate region 30, which is adjacent to the first trench 50 and opposite to the further collector region 43, comprises a further emitter region 45. Next, the resist layer is removed and a further base region 41 is formed by implantation of a p-type dopant, such as boron. The bottom of the first trench 50 forms the top of the further base region 41, which reaches through to the substrate insulation region 10, whereby the further base region 41 replaces the portion of the substrate region 30 that is located at the bottom of the first trench 50.

A wet etch removes the portion of the first insulation liner layer 101 which is exposed in the first trench 50. A base region 210 is formed with epitaxial growth covering all exposed surfaces, as is illustrated in FIG. 10. The base region 210 preferably comprises a SiGe:C layer, but any other p-type semiconductor material may also be applied. A portion of the base region 210 covers a portion of the further base region 410 in the first trench 50. Thereafter, a second insulation liner layer 220 is deposited on the base region 210.

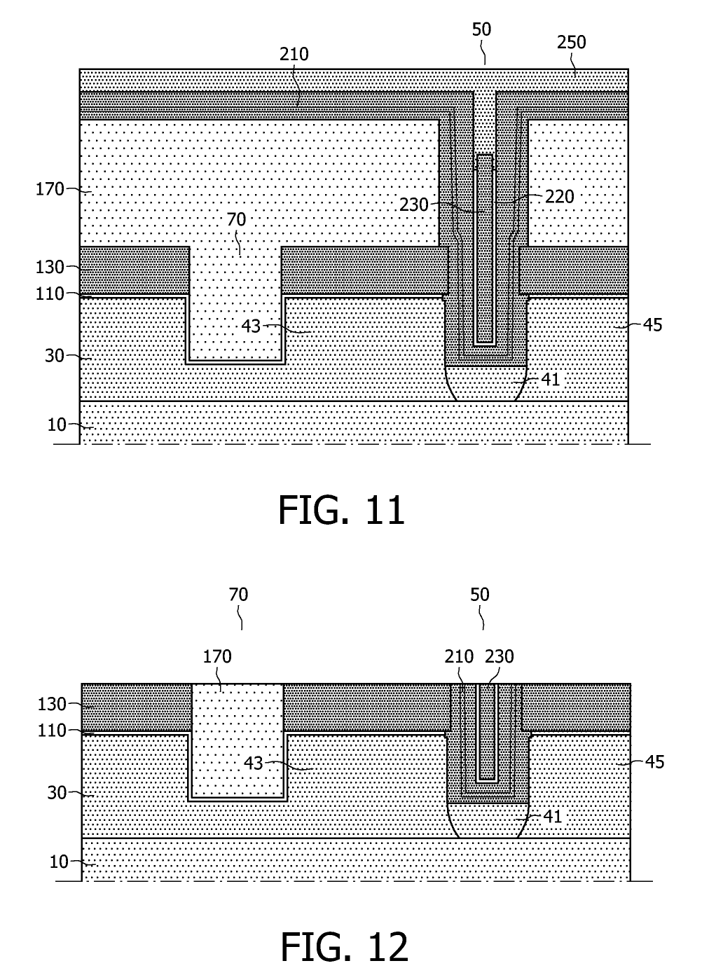

Next, second spacers 230 are formed by depositing and anisotropic etching of silicon nitride. The first trench 50 has such a dimension and/or shape that the silicon nitride material of the second spacers covers the bottom of the first trench 50 and fills a portion of the first trench 50. A wet etch removes the exposed portions of the second insulation liner layer 220 and an emitter region 250 is formed by deposition or growth of an n-type polysilicon or mono-silicon layer, as is shown in FIG. 11. The emitter region 250 fills a remaining portion of the first trench 50 and extends over the base region 210.

At this point the standard STI fabrication method is continued with planarizing the surface using CMP, which method is able to planarize and remove not only the second insulation layer 170, but also the emitter region 250 and the base region 210, which regions may comprise mono-silicon, poly-silicon or SiGe. After the CMP step the first insulation layer 130 and a top portion of the second spacers 230 are exposed, and the emitter region 250 is removed completely, as is illustrated in FIG. 12.

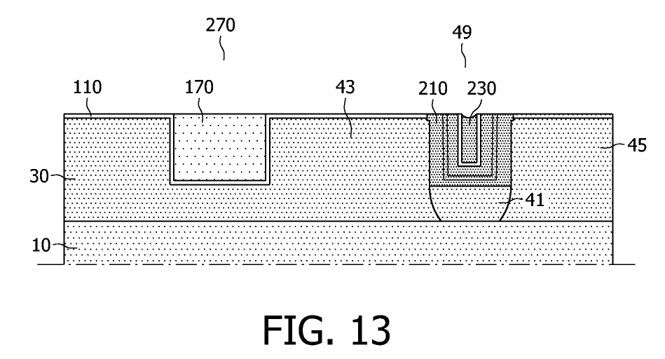

Thereafter a portion of the base region 210 is removed by an isotropic silicon etch or a wet oxidation step. This fabrication step is introduced in the standard STI fabrication method to enable an improved planar surface of the lateral bipolar transistor. The standard STI fabrication method continues with a wet etch which removes the first insulation layer 130, a portion of the second insulation layer 170 and a portion of the second spacers 230, and results in a planar surface as is illustrated in FIG. 13. At this point an STI region 270 is formed in the second trench 70, which is filled with the second insulation layer 170. Further a lateral bipolar transistor 490 is formed simultaneously in the first trench 50 comprising the further collector region 430, the further emitter region 450, the further base region 410 and the base region 210. The base region 210 will provide the largest collector current, in the case that the base region 210 comprises SiGe. In summary, the fabrication method has formed a lateral bipolar transistor in a trench that is normally used as a trench for an STI region.

From this point onwards the standard semiconductor fabrication continues with the forming of other devices, such as CMOS transistors. The lateral bipolar transistor maybe covered with an insulation layer to reduce the influence of the further fabrication steps on the lateral bipolar transistor. This insulation layer may be patterned using an existing mask, such as a silicide protection mask. Then a base contact region, which electrically connects to the further base region 41, a collector contact region, which connects electrically to the further collector region 43, and an emitter contact region, which connects electrically to the further emitter region 45, may be formed by providing a metal layer on the appropriate regions.

The fabrication method for the vertical bipolar transistor or for the lateral bipolar transistor may also simultaneously provide the vertical bipolar transistor 29 in the first trench 5 and the lateral bipolar transistor 49 in a third trench. In the second trench 7 the shallow trench isolation region 27 and/or 270 is provided simultaneously. For this purpose the spacers 15 may be omitted and an extra masking step may be added which defines the regions in which the collector region 19 and the further base region 41 are formed.

The above-mentioned embodiments are examples of the fabrication of NPN-type bipolar transistors. However, it should be noted that the invention is not limited to NPN-type bipolar transistors, because the above-mentioned fabrication method can be modified to also include PNP-type bipolar transistors by replacing the n-type material by p-type material and vice-versa.

In summary, the invention provides a method for fabricating a bipolar transistor applying a standard shallow trench isolation fabrication method to simultaneously form a vertical bipolar transistor or a lateral bipolar transistor in a first trench and a shallow trench isolation region in a second trench. Further, the fabrication method may simultaneously form a vertical bipolar transistor in the first trench, a lateral bipolar transistor in a third trench and a shallow trench isolation region in the second trench.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of other elements or steps than those listed in a claim. The word “a” or “an” preceding an element does not exclude the presence of a plurality of such elements.

1. A method for fabricating a bipolar transistor, the method comprising:
providing a first insulation layer on a further substrate region, which overlies a substrate region,
forming a first trench and a second trench in the first insulation layer and in the further substrate region, each trench having a bottom,
forming a second insulating layer, thereby covering the first insulation layer and filling the first trench and the second trench,
removing the second insulation layer from the first trench,
forming a first transistor region in a portion of the further substrate region, which is located at the bottom of the first trench,
forming a second transistor region on a portion of the first transistor region,
forming a third transistor region on a portion of the second transistor region, and planarizing the exposed surfaces, thereby exposing the first insulation layer and
forming a shallow trench isolation region in the second trench.

2. The method as claimed in claim 1, in which the bipolar transistor comprises a vertical bipolar transistor in which the first transistor region comprises a collector region, the second transistor region comprises a base region, and the third transistor region comprises an emitter region.

3. The method as claimed in claim 1, in which the bipolar transistor comprises a lateral bipolar transistor in which the first transistor region comprises a base region, the second transistor region comprises a further base region, the substrate region adjacent to the first trench comprises a further emitter region and a further collector region, wherein the further emitter region be and the further collector region are located on opposite sides of the first trench.

4. The method as claimed in claim 2, in which the vertical bipolar transistor is fabricated in the first trench and the lateral bipolar transistor is fabricated simultaneously in a third trench, the method further including a step of forming a masking layer before forming the first transistor region.

5. The method as claimed in claim 1, in which the substrate region comprises an insulating material.

6. The method as claimed in claim 1, in which the second transistor region comprises SiGe:C.
